(19) United States
(12) Patent Application Publication
(10) Pub. No.: US 2016/0273961 A1
(43) Pub. Date: Sep. 22, 2016

(54) IMAGE SENSOR

(71) Applicant: SK hynix Inc., Gyeonggi-do (KR)

(72) Inventor: Do-Hwan KIM, Gyeonggi-do (KR)

(21) Appl. No.: 14/743,891

(22) Filed: Jun. 18, 2015

(30) Foreign Application Priority Data
Mar. 20, 2015 (KR) 10-2015-0039049

(51) Int. Cl. G01J 1/44; H01L 27/146

(52) U.S. Cl. CPC G01J 1/44; H01L 27/14643; H01L 27/14612; H01L 27/14636

(57) ABSTRACT

An image sensor includes a light receiving section suitable for generating photocharges corresponding to incident light, a first driving section suitable for transferring a first output voltage corresponding to a first voltage to a first column line based on the photocharges, a second driving section suitable for transferring a second output voltage corresponding to a second voltage to a second column line based on the photocharges, and an output section suitable for outputting an image signal based on the first and second output voltages.

### CROSS-REFERENCE TO RELATED APPLICATIONS

The present document claims priority of Korean Patent Application No. 10-2015-0039049, entitled “IMAGE SENSOR” and flied on Mar. 20, 2015, which is incorporated herein by reference in its entirety.

### BACKGROUND

Various embodiments of the present invention relate to a semiconductor design technology, and more particularly, to an image sensor.

Image sensors convert optical images into electrical signals. Recently, with the development of the computer and communication industries, there has been increased demand for image sensors with improved performance in various fields, such as digital cameras, camcorders, smart phones, game machine, security camera, medical micro cameras, robots and the like.

### SUMMARY

Various embodiments of the present invention are directed to an image sensor with improved performance.

In an embodiment, an image sensor may include: a light receiving section suitable for generating photocharges corresponding to incident light; a first driving section suitable for transferring a first output voltage corresponding to a first voltage to a first column line based on the photocharges; a second driving section suitable for transferring a second output voltage corresponding to a second voltage to a second column line based on the photocharges; and an output section suitable for outputting an image signal based on the first and second output voltages.

The first driving section and the second driving section may include one or more MOS transistors, respectively, and have conductivity types that are complementary. The first driving section and the second driving section may operate based on the same amount of photocharge at the same time. The first driving section may include a first source follower transistor suitable for generating the first output voltage corresponding to the first voltage based on the photocharges, and the second driving section may include a second source follower transistor suitable for generating the second output voltage corresponding to the second voltage based on the photocharges. The first and second source follower transistors may include MOS transistors having conductivity types that are complementary. The first voltage may be higher than the second voltage, and the first source follower transistor may include an nMOS transistor and the second source follower transistor may include a pMOS transistor. The first driving section may include a first selection transistor suitable for transferring the first output voltage to the first column line based on a first selection signal applied to a first row line, and the second driving section may include a second selection transistor suitable for transferring the second output voltage to the second column line based on a second selection signal applied to a second row line. The first and second selection transistors may include MOS transistors having conductivity types that are complementary. The second selection signal may be an inverted signal of the first selection signal. The light receiving section may include: a photoelectric conversion element suitable for generating the photocharges based on the incident light; a floating diffusion node suitable for storing the photocharges generated in the photoelectric conversion element; a transmission transistor suitable for transferring the photocharges generated in the photoelectric conversion element to the floating diffusion node based on a transmission signal; and a reset transistor suitable for resetting the floating diffusion node based on a reset signal.

In an embodiment, an image sensor may include: a first node set to a first voltage; a second node set to a second voltage; a light receiving section coupled between the first node and the second node; a first source follower transistor coupled to the first node; a first selection transistor coupled between the first source follower transistor and a first column line and controlled by a first row line; a second source follower transistor coupled to the second node; a second selection transistor coupled between the second source follower transistor and a second column line and controlled by a second row line; and an output section coupled to the first and second column lines.

The first and second source follower transistors and the first and second selection transistors may include MOS transistors having conductivity types that are complementary. The first source follower transistor and the second source follower transistor may have conductivity types that are complementary. The first source follower transistor and the first selection transistor may have the same conductivity type, and the second source follower transistor and the second selection transistor may have the same conductivity type. The output section may merge values of the first column line and the second column line to provide the merged value to one final column line. The light receiving section may include: a photoelectric conversion element coupled to the second node; a reset transistor coupled to the first node; and a transmission transistor coupled between the photoelectric conversion element and the reset transistor. Gates of the first source follower transistor and the second source follower transistor may be coupled to a floating diffusion node that is a common node of the transmission transistor and the reset transistor.

In an embodiment, an image sensor may include: a pixel array in which a plurality of unit pixels are arranged in a matrix structure; a plurality of row lines each including first and second conductive row lines driven by differential selection signals generated in a row driver unit; a plurality of column lines each including first and second conductive column lines corresponding to first and second output voltages generated in a selected unit pixel; an output control unit suitable for generating an image signal based on the first and second output voltages, wherein the output control unit includes a plurality of output sections corresponding to the respective column lines; and a sampling unit coupled to the output control unit to sample the image signal.

In an embodiment, an image sensor may include: a first substrate including a plurality of light receiving sections each suitable for generating photocharges based on incident light; a first circuit layer formed on the first substrate; a second circuit layer formed on a second substrate; and a connector suitable for electrically coupling the first circuit layer to the second circuit layer, wherein each of a plurality of unit pixels corresponding to the respective light receiving sections may include; a first driving section suitable for transferring a first output voltage corresponding to a first voltage to a first column line based on the photocharges generated in the light receiving section; a second driving section suitable for transferring a second output voltage corresponding to a second voltage to a second column line based on the photocharges generated in the light receiving section; and an output section suitable for outputting an image signal based on the first and second output voltages.

The first substrate and the second substrate may be bonded such that the first circuit layer and the second circuit layer face each other. The first driving section and the second driving section may include one or more MOS transistors, respectively, and have conductivity types that are complementary. The first circuit layer may include the first driving section, and the second circuit layer may include the second driving section.

### BRIEF DESCRIPTION OF THE DRAWINGS

FIG. 1 is a block diagram illustrating an image sensor.

FIG. 2 is a detailed diagram of a unit pixel shown in FIG. 1.

FIG. 3 is a block diagram illustrating an image sensor in accordance with an embodiment of the present invention.

FIG. 4 is a detailed diagram of a unit pixel shown in FIG. 3.

FIG. 5 is a cross-sectional view illustrating an image sensor in accordance with an embodiment of the present invention.

FIG. 6 is a diagram illustrating an electronic device in accordance with an embodiment of the present invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure be thorough and complete, and will fully convey the scope of the present invention to those skilled in the art. Throughout the disclosure, like reference numerals refer to like parts throughout the various figures and embodiments of the present invention.

The drawings are not necessarily to scale and, in some instances, proportions may have been exaggerated to clearly illustrate features of the embodiments. When a first layer is referred to as being “on” a second layer or “on” a substrate, it not only refers to where the first layer is formed directly on the second layer or the substrate but also to where a third layer exists between the first layer and the second layer or the substrate. It is also noted that in this specification, “connected/coupled” refers to one component not only directly coupling another component but also indirectly coupling another component through an intermediate component. In addition, a singular form may include a plural form as long as it is not specifically mentioned.

Embodiments of the present invention to be described later provides an image sensor with improved signal-to-noise ratio (SNR).

The image sensors include charge coupled devices (CCDs) and CMOS image sensors (CISs). Since a CIS has a simple driving scheme and may be fabricated using CMOS process technology, it generally has reduced fabrication cost. A CIS includes a pixel array in which a plurality of unit pixels are arranged in a matrix structure. Each of the unit pixels may include a photoelectric conversion element for generating photocharges from incident light and an output circuit for outputting an image signal in response to the generated photocharges. The output circuit may include a plurality of pixel transistors and may be realized in various architectures. The output circuit may be realized by four pixel transistors.

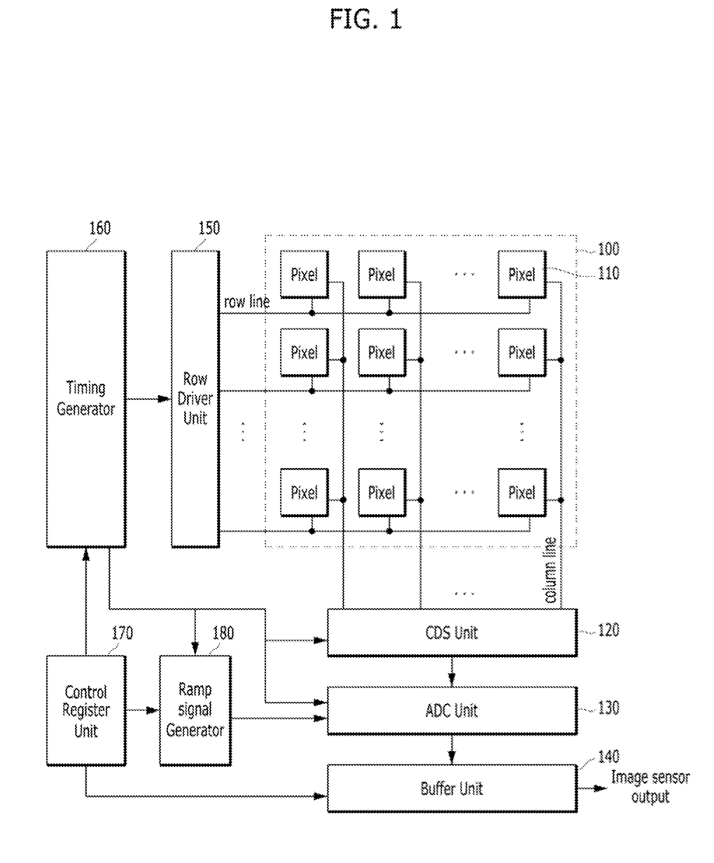

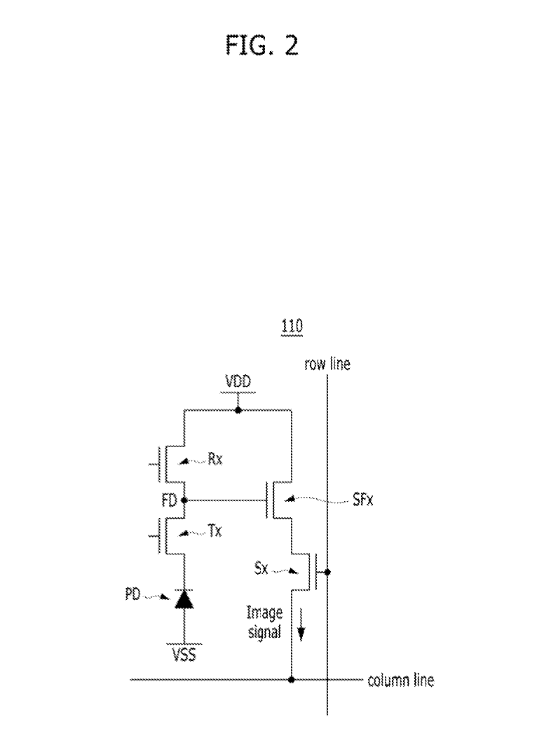

FIG. 1 is a block diagram illustrating an image sensor, and FIG. 2 is a circuit diagram of an image sensor unit pixel.

As illustrated in FIGS. 1 and 2, the image sensor includes a pixel array 100 in which a plurality of unit pixels 110 are arranged in a matrix structure, a correlated double sampling (CDS) unit 120, an analog-to-digital converter (ADC) unit 130, a buffer unit 140, a row driver unit 150, a timing generator 160, a control register unit 170, and a ramp signal generator 180.

The timing generator 160 generates control signals for controlling the operations of the row driver unit 150, the correlated double sampling unit 120, the analog-to-digital converter unit 130, and the ramp signal generator 180. The control register unit 170 generates control signals for controlling the operations of the ramp signal generator 180, the timing generator 160, and the buffer unit 140.

The row driver unit 150 drives the pixel array 100 in units of row lines. For example, the row driver unit 150 generates a selection signal capable of selecting one row line from a plurality of row lines. The unit pixels 110 are coupled to each of the row lines. One row line is coupled to each of the unit pixels 110.

Each of the unit pixels 110 detects incident light and outputs an image reset signal and an image signal to the correlated double sampling unit 120 through a column line. The correlated double sampling unit 120 performs sampling for each of the received image reset signal and image signal. The unit pixels 110 are respectively coupled to a plurality of column lines, and one column line is coupled to each of the unit pixels 110. The analog-to-digital converter unit 130 compares a ramp signal outputted from the ramp signal generator 180 with a sampling signal outputted from the correlated double sampling unit 120, and outputs a comparison signal. The analog-to-digital converter unit 130 counts a level transition time of the comparison signal according to a clock signal provided from the timing generator 160 and outputs a count value to the buffer unit 140. The ramp signal generator 180 operates under the control of the timing generator 160.

The buffer unit 140 stores a plurality of digital signals outputted from the analog-to-digital coverter unit 130, and sense-amplifies and outputs the digital signals. Accordingly, the buffer unit 140 includes a memory (not illustrated) and a sense amplifier (not illustrated). The memory stores the count value that indicates a count value associated with signals outputted from the unit pixels 110. The sense amplifier senses and amplifies respective count values outputted from the memory.

Each of the unit pixels 110 includes a photoelectric conversion element PD, a transmission transistor Tx, a reset transistor Rx, a source follower transistor SFx, and a selection transistor Sx.

The photoelectric conversion element PD may be a photodiode. The photoelectric conversion element PD is coupled between a second node VSS set to a ground voltage and the transmission transistor Tx. The reset transistor Rx is coupled between the transmission transistor Tx and a first node set to a power supply voltage VDD, and a floating diffusion node FD is coupled between the reset transistor Rx and the transmission transistor Tx. A gate of the source follower transistor SFx is coupled to the floating diffusion node FD. One side of the source follower transistor SFx is coupled to the first node, and the other side thereof is coupled to the selection transistor Sx. A gate of the selection transistor Sx is coupled to the row line extending from the row driver unit 150, and the selection transistor Sx is coupled to the column line. The column line is coupled to the correlated double sampling unit 120.

When the selection transistor Sx is turned on in response to a selection signal applied from the row driver unit 150 through the row line, a specific unit pixel is selected. Then, when incident light introduced into the photoelectric conversion element PD has been blocked, the reset transistor Rx is turned on to reset the floating diffusion node FD. Then, the reset transistor Rx is turned off, and incident light is irradiated into the photoelectric conversion element PD for a predetermined time, for example, during an integration period, so that photocharges are generated. After the integration period, the transmission transistor Tx is turned on, the photocharges generated in the photoelectric conversion element PD is transferred to the floating diffusion node FD, and the transferred photocharges are stored in the floating diffusion node FD. A gate bias of the source follower transistor SFx changes in proportion to the amount of photocharge stored in the floating diffusion node FD, and the output voltage corresponding to the power supply voltage, that is, an image signal is outputted to the column line in response to the amount of photocharge stored in the floating diffusion node FD.

A lot of research has been put into improving pixel transistors and reducing noise in image sensors, such as those shown in FIGS. 1 and 2. For example, flicker noise from the source follower transistor SFx is known to cause image degradation. However, noise due to threshold voltage variations and low frequency power noise are still major issues to be solved.

In this regard, an embodiment of the present invention to be described later provides an image sensor including complementary source followers capable of resolving the aforementioned noise concerns. Since the complementary source followers generate final outputs by adding (or merging) the output of an nMOS transistor with the output of a pMOS transistor, it is possible to control the threshold voltage variations and the low frequency variations. That is, since the polarities of threshold voltages of the nMOS transistor and the pMOS transistor are opposite, they are offset, so that the final output is not affected by the threshold voltages. Furthermore, since power noises also have opposite polarities, the final output is not affected by the power noises.

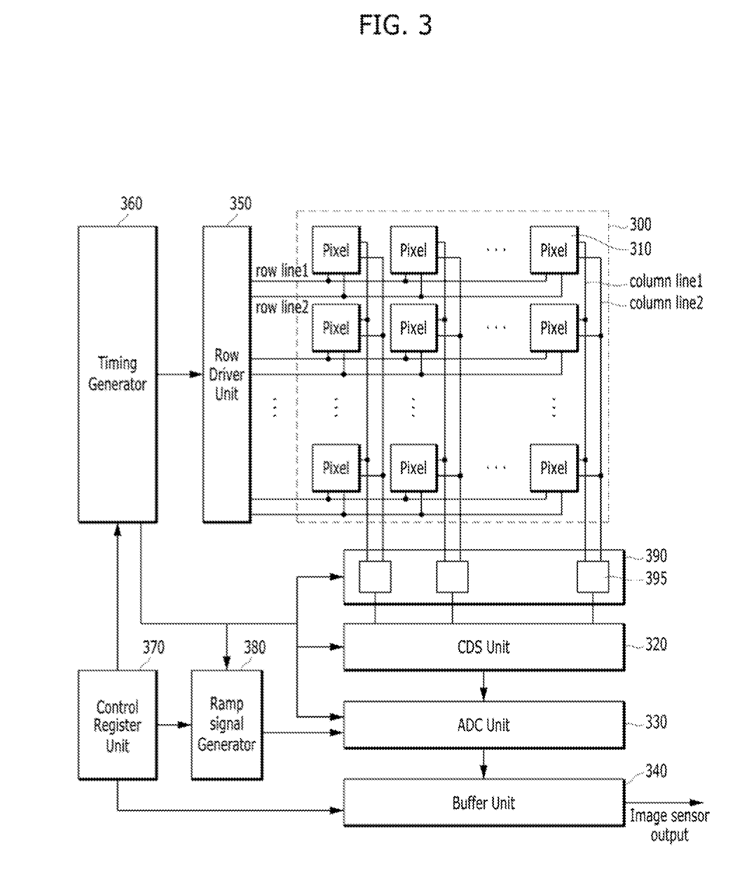

FIG. 3 is a block diagram illustrating an image sensor in accordance with an embodiment of the present invention.

As illustrated in FIG. 3, the image sensor may include a pixel array 300 in which a plurality of unit pixels 310 are arranged in a matrix structure, a correlated double sampling (CDS) unit 320, an analog-to-digital converter (ADC) unit 330, a buffer unit 340, a row driver unit 350, a timing generator 360, a control register unit 370, a ramp signal generator and an output control unit 390.

The timing generator 360 generates control signals for controlling the operations of the row driver unit 350, the correlated double sampling unit 320, the analog-to-digital converter unit 330, the ramp signal generator 380, and the output control unit 390. The control register unit 370 generates control signals for controlling the operations of the ramp signal generator 380, the timing generator 360, and the buffer unit 340.

The row driver unit 350 drives the pixel array 300 in units of row lines. For example, the row driver unit 350 may generate a selection signal capable of selecting one row line from a plurality of row lines. Two row lines, for example, a first row line (row line 1) and a second row line (row line 2) may be coupled to each of the unit pixels 310. The first row line and the second row line may be driven by differential selection signals generated in the row driver unit 350.

A column line including first and second conductive lines corresponding to first and second output voltages may be coupled to each of the unit pixels 310. The first column line (column line 1) and the second column line (column line 2) may be coupled to each of the unit pixels 310. The first column line and the second column line may be coupled to an output section 395, and the output section 395 may output an image reset signal and an image signal to the correlated double sampling unit 320. A plurality of output sections 395 may be arranged at one side of the pixel array 300 to correspond to the columns of the pixel array 300, and the output control unit 390 may include the output sections 395.

The correlated double sampling unit 320 performs sampling for each of the received image reset signal and image signal received from the output control unit 390 including the output sections 395. The analog-to-digital converter unit 330 compares a ramp signal outputted from the ramp signal generator 380 with a sampling signal outputted from the correlated double sampling unit 320, and outputs a comparison signal. The analog-to-digital converter unit 330 counts a level transition time of the comparison signal according to a clock signal provided from the timing generator 360, and outputs a count value to the buffer unit 340. The ramp signal generator 380 may operate under the control of the timing generator 360.

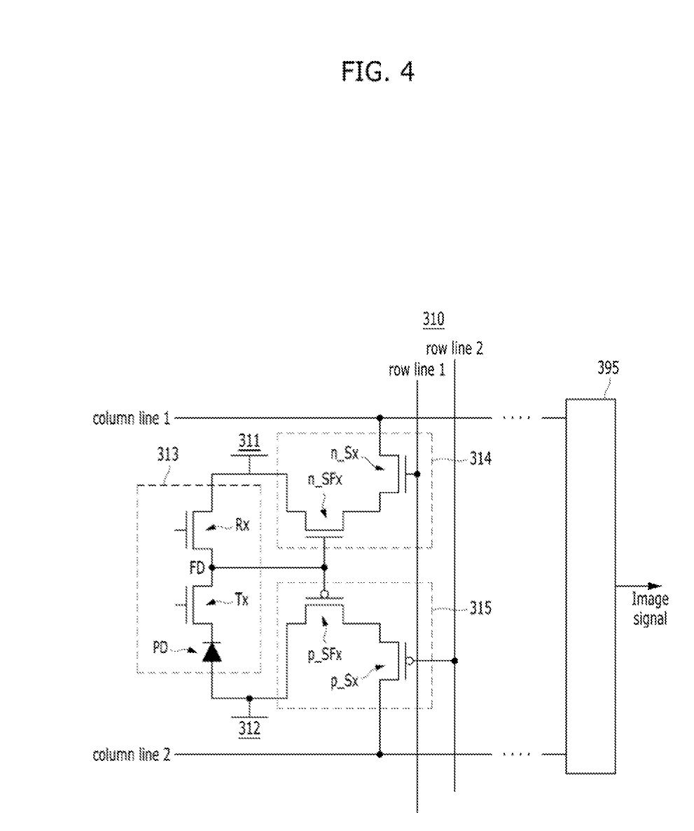

FIG. 4 is a detailed diagram of the unit pixel 310 shown in FIG. 3.

Referring to FIG. 4, the unit pixel 310 may include a light receiving section 313, a first driving section 314, a second driving section 315, and an output section. The light receiving section 313 is coupled between a first node 311 set to a first voltage and a second in node 312 set to a second voltage and generates photocharges in response to incident light. The first driving section 314 transfers a first output voltage corresponding to the first voltage to the first column line in response to the photocharges provided by the light receiving section 313. The second driving section 315 transfers a second output voltage corresponding to the second voltage to the second column line in response to the photocharges provided by the light receiving section 313. The output section is coupled to the first column line and the second column line and outputs an image signal in response to the first output voltage and the second output voltage. The first driving section 314 and the second driving section 315 may have conductivity types that are complementary. The first driving section 314 the second driving section 315 may operate in response to the same amount of photocharges at the same time.

The light receiving section 313 coupled between the first node 311 and the second node 312 may include a photoelectric conversion element PD for generating photocharges in response to incident light, a floating diffusion node FD for storing the generated photocharges, a transmission transistor Tx for transferring the photocharges generated in the photoelectric conversion element. PD to the floating diffusion node FD in response to a transmission signal, and a reset transistor Rx for resetting the floating diffusion node FD in response to a reset signal. The transmission signal and the reset signal may be applied to a gate of the transmission transistor Tx and a gate of the reset transistor Rx, respectively.

The first voltage of the first node 311 and the second voltage of the second node 312 are different, and the first voltage may be higher than that of the second voltage. For example, the first voltage may be a power supply voltage VDD and the second voltage may be a ground voltage VSS. The photoelectric conversion element PD may include a photodiode. The photoelectric conversion element PD may be coupled between the second node 312 and the transmission transistor Tx. The reset transistor Rx may be coupled between the transmission transistor Tx and the first node 311, and the floating diffusion node FD may be coupled between the reset transistor Rx and the transmission transistor Tx. The transmission transistor Tx and the reset transistor Rx may include an MOS transistor. For example, the transmission transistor Tx may be an nMOS transistor and the reset transistor Rx may be an nMOS transistor or a pMOS transistor.

The first driving section 314 may include a first source follower transistor n_SFx and a first selection transistor n_Sx. The first source follower transistor n_SFx may be coupled between the first node 311 and the first selection transistor n_Sx, and a gate of the first source follower transistor n_SFx may be coupled to the floating diffusion node FD. The first source follower transistor n_SFx may generate the first output voltage corresponding to the first voltage in response to the photocharges generated in the light receiving section 313. The first selection transistor n_Sx may be coupled between the first source follower transistor n_SFx and the first column line, and a gate of the first selection transistor n_Sx may be coupled to the first row line. The first selection transistor n_Sx may transfer the first output voltage generated in the first source follower transistor n_SFx to the first column line in response to a first selection signal applied through the first row line.

The second driving section 315 may include a second source follower transistor p_SFx and a second selection transistor p_Sx. The second source follower transistor p_SFx may be coupled between the second node 312 and the second selection transistor p_Sx, and a gate of the second source follower transistor p_SFx may be coupled to the floating diffusion node FD. The second source follower transistor p_SFx may generate the second output voltage corresponding to the second voltage in response to the photocharges generated in the light receiving section 313. The second output voltage may be generated in response to the same amount of photocharges at the same time as that of the first output voltage. The second selection transistor p_Sx may be coupled between the second source follower transistor p_SFx and the second column line, and a gate of the second selection transistor p_Sx may be coupled to the second row line. The second selection transistor p_Sx may transfer the second output voltage generated in the second source follower transistor p_SFx to the second column line in response to a second selection signal applied through the second row line. When the second selection signal is applied to the second row line may be the same as when the first selection signal is applied to the first row line.

The first source follower transistor n_SFx, the second source follower transistor p_SFx, the first selection transistor n_Sx, and the second selection transistor p_Sx may include MOS transistors having conductivity types that are complementary. In detail, to prevent characteristic degradation caused by noise, the first source follower transistor n_SFx and the second source follower transistor p_SFx may have conductivity types that are complementary. The first selection transistor n_Sx and the second selection transistor p_Sx may also have conductivity types that are complementary. The first source follower transistor n_SFx and the first selection transistor n_Sx may have the same conductivity type, and the second source follower transistor p_SFx and the second selection transistor p_Sx may also have the same conductivity type. The conductivity types of the first selection transistor n_Sx and the second selection transistor p_Sx may be adjusted to improve the degree of integration of the image sensor. In the embodiment, since the first source follower transistor n_SFx is coupled to the first node 311 set to the first voltage higher than the second voltage, the first source follower transistor n_SFx may be an nMOS transistor, and the second source follower transistor p_SFx may be a pMOS transistor. Accordingly, the first selection transistor n_Sx may be an nMOS transistor, and the second selection transistor p_Sx may be a pMOS transistor. In this example, the second selection signal applied to the second selection transistor p_Sx may be obtained by inverting the first selection signal. That is the first selection signal and the second selection signal may be differential signals.

The first selection transistor n_Sx and the second selection transistor p_Sx may also be MOS transistors having the same conductivity type. The first selection signal and the second selection signal may be the same signal or the first selection transistor n_Sx and the second selection transistor p_Sx may share one row line. Alternatively, the first driving section 314 and the second driving section 315 may share one selection transistor. As described above, when the first selection transistor n_Sx and the second selection transistor p_Sx have the same conductivity type, since the first driving section 314 and the second driving section 315 have some configurations in common, the degree of difficulty in design and fabrication may considerably increase considerably.

The output section 395 performs a role of generating an image signal having no noise components from the first output voltage and the second output voltage, for example, noise components caused by threshold voltage variations of a transistor or low frequency variations due to power noise. To this end, the image signal generated in the output section 395 may be generated by adding the first output voltage to the second output voltage. To generate such an image signal, the output section 395 may have a configuration for merging values of the first column line and the second column line and providing the merged value to one final column line. The output section 395 may provide the image signal having no noise components, because the first source follower transistor n_SFx and the second source follower transistor p_SFx for generating the first output voltage and the second output voltage in response to the photocharges generated in the light receiving section 313 have conductivity types that are complementary. That s, since threshold voltages loaded on the first output voltage and the second output voltage have opposite polarities, the image signal obtained by adding the first output voltage to the second output voltage is not affected by threshold voltage variations of the pixel transistor. Furthermore, since low frequency variations due to power noises loaded on the first output voltage and the second output voltage also have opposite polarities, the image signal obtained by adding the first output voltage to the second output voltage is not affected by the power noise.

Hereinafter, an operation of the unit pixel of the image sensor in accordance with the embodiment will be described. The first selection transistor n_Sx and the second selection transistor p_Sx are simultaneously turned on in response to the first selection signal and the second selection signal respectively applied to the first row line and the second row line from the row driver unit 350. The second selection signal may be obtained by inverting the first selection signal. When incident light introduced to the photoelectric conversion element PD has been blocked, the reset transistor Rx is turned on to reset the floating diffusion node FD. Then, the reset transistor Rx is turned off, and incident light is irradiated into the photoelectric conversion element PD for a predetermined time, for example, an integration period, so that photocharges are generated. The reset transistor Rx may keep the turn-on state even in the integration period, making it is possible to prevent characteristic degradation caused by power noises more effectively. After the integration period, the transmission transistor Tx is turned on, the photocharges generated in the photoelectric conversion element PD are transferred to the floating diffusion node FD, and the transferred photocharges are stored in the floating diffusion node FD. Gate biases of the first source follower transistor n_SFx and the second source follower transistor p_SFx change in proportion to the amount of the photocharge stored in the floating diffusion node FD, and the first output voltage corresponding to the first voltage and the second output voltage corresponding to the second voltage are transferred to the first column line and the second column line in response to the amount of photocharge stored in the floating diffusion node FD. The first output voltage and the second output voltage are transferred to the output section 395 through the first column line and the second column line, and the image signal is output from the output section 395 in response to the first output voltage and the second output voltage. The image signal output from the output section 395 is provided to the correlated double sampling unit 320.

As described above, the image sensor includes the first driving section 314 and the second driving section 315 having different conductivity types, thereby alleviating noise caused by threshold voltage variations of transistors and low frequency variations due to power noise. Consequently, it is possible to improve the signal-to-noise ratio characteristics of the image sensor.

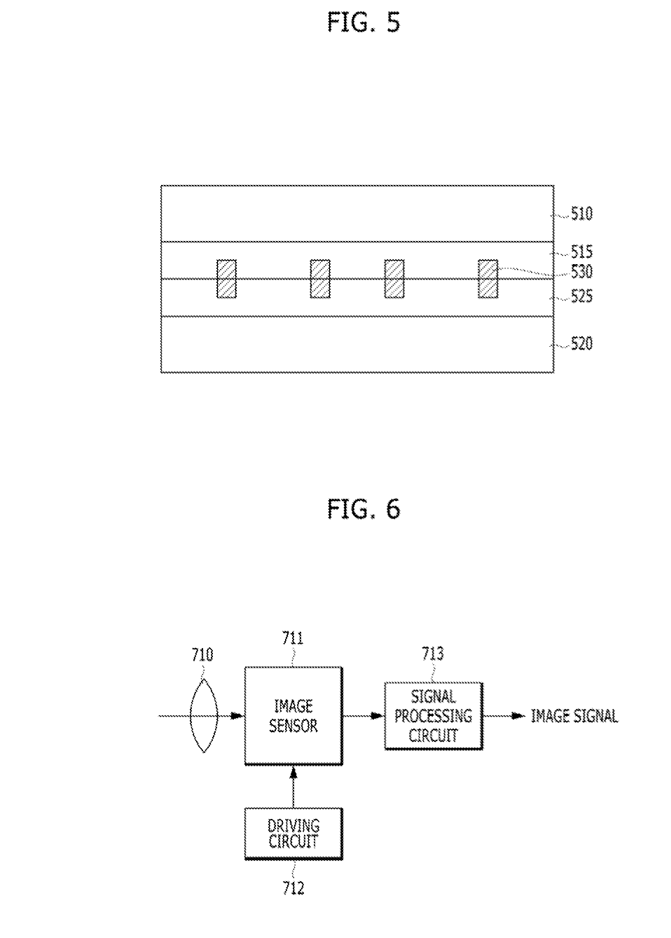

Furthermore, the image sensor includes the first driving section 314 and the second driving section 315 thereby alleviating noise concerns and simultaneously improving integration of the image sensor. This will be described in detail with reference to FIG. 5.

In the aforementioned image sensor in accordance with the embodiment, complementary transistors should be realized in the pixel array. To this end, since a plurality of wells having various conductivity types, for example, n well for pMOS transistors and p wells for nMOS transistors should be formed in the pixel array, it is not possible to realize an image sensor that is highly integrated. A CMOS image sensor (CIS) may be classified into a front-side illumination type CIS and a back-side illumination type CIS. It is known that the back-side illumination type CIS may realize operation characteristics (for example, sensitivity) superior to those of the front-side illumination type CIS. In addition, the back-side illumination type CIS should simultaneously have a device wafer and a carrier wafer in processes. Accordingly, an embodiment of the present invention to be described later provides an image sensor capable of improving the degree of integration by using the characteristics of the back-side illumination type CIS simultaneously having the device wafer and the carrier wafer, even though a first light receiving section and a second light receiving section have complementary conductivity types. Hereinafter, convenience, a detailed description of the blocks and the unit pixel of the aforementioned image sensor will be omitted.

FIG. 5 is a cross-sectional view illustrating an image sensor in accordance with an embodiment of the present invention.

As illustrated in FIG. 5, the image sensor may include a pixel array in which a plurality of unit pixels are arranged in a matrix structure. The pixel array may include a first substrate 510 including a plurality of light receiving sections for generating photocharges in response to incident light, a first circuit layer 515 formed on the first substrate 510, a second circuit layer 525 formed on a second substrate 520, and a connector 530 for electrically connecting the first circuit layer 515 to the second circuit layer 525. The pixel array may include a stack structure in which the first substrate 510 and the second substrate 520 have been bonded such that the first circuit layer 515 and the second circuit layer 525 face each other. A light incident surface may be the rear surface of the first substrate 510.

In the pixel array, each of the unit pixels arranged in a matrix structure may include the light receiving section for generating photocharges in response to incident light, a first driving section for transferring a first output voltage corresponding to a first voltage to a first column line in response to the photocharges, a second driving section for transferring a second output voltage corresponding to a second voltage to a second column line in response to the photocharges, and an output section for outputting an image signal in response to the first output voltage and the second output voltage. The first driving section and the second driving section may include one or more MOS transistors having conductivity types that are complementary. For example, the first driving section may include a first source follower transistor and a first selection transistor, where these transistors may be nMOS transistors. The second driving section may include a second source follower transistor and a second selection transistor, where these transistors may be pMOS transistors (see FIGS. 3 and 4).

In the pixel array, even though each of the unit pixels includes the first driving section and the second driving section having conductivity types that are complementary, the first circuit layer 515 may include the first driving section and the second circuit layer 525 may include the second driving section to improve the degree of integration. That is, the first circuit layer 515 on the first substrate 510 may include only a transistor having a first conductivity type, for example, an n type channel, and the second circuit layer 525 on the second substrate 520 may include only a transistor having a second conductivity type, for example, a p type channel.

The aforementioned image sensor in accordance with the embodiment may be applied to various electronic devices. Hereinafter, with reference to FIG. 6, an example of an electronic device including the image sensor in accordance with the embodiment will be described. FIG. 6 illustrates an example of a digital still camera capable of capturing a still image.

FIG. 6 is a diagram illustrating an electronic device in accordance with the embodiment of the present invention.

As illustrated in FIG. 6, the electronic device may include an optical lens 710, an image sensor 711, a driving circuit 712, and a signal processing circuit 713. The image sensor 711 may have the same configuration as the image sensor shown in FIGS. 3 to 5.

The optical lens 710 forms an image of incident light from an object on an imaging surface of the image sensor 711. Thus, charge corresponding to a signal is accumulated in the image sensor 711 for a predetermined period. The driving circuit 712 supplies a transmission operation signal of the image sensor 711. The signal transmission of the image sensor 711 is performed by a driving signal (or a timing signal) supplied from the driving circuit 712. The signal processing circuit 713 performs various types of signal processing. An image signal subjected to the signal processing is stored in a storage medium such as a memory or is output to a monitor.

Although various embodiments have been described for illustrative purposes, it will be apparent to those skilled in the art that various changes and modifications may be made without departing from the spirit and scope of the invention as defined in the following claims.

What is claimed:

1. An image sensor comprising:
a light receiving section suitable for generating photocharges corresponding to incident light;
a first driving section suitable for transferring a first output voltage corresponding to a first voltage to a first column line based on the photocharges;
a second driving section suitable for transferring a second output voltage corresponding to a second voltage to a second column line based on the photocharges; and
an output section suitable for outputting an image signal based on the first and second output voltages.

2. The image sensor of claim wherein the first driving section and the second driving section include one or more MOS transistors, respectively, and have conductivity types that are complementary.

3. The image sensor of claim 1, wherein the first driving section and the second driving section operate based on the same amount of photocharge at the same time.

4. The image sensor of claim 1, wherein the first driving section includes a first source follower transistor suitable for generating the first output voltage corresponding to the first voltage based on the photocharges, and
the second driving section includes a second source follower transistor suitable for generating the second output voltage corresponding to the second voltage based on the photocharges.

5. The image sensor of claim 4, wherein the first and second source follower transistors include MOS transistors having conductivity types that are complementary.

6. The image sensor of claim 4, wherein the first voltage is higher than the second voltage, and the first source follower transistor includes an nMOS transistor and the second source follower transistor includes a pMOS transistor.

7. The image sensor of claim wherein the first driving section includes a first selection transistor suitable for transferring the first output voltage to the first column line based on a first selection signal applied to a first row line, and the second driving section includes a second selection transistor suitable for transferring the second output voltage to the second column fine based on a second selection signal applied to a second row line.

8. The image sensor of claim 7, wherein the first and second selection transistors include MOS transistors having conductivity types that are complementary.

9. The image sensor of claim 7, wherein the second selection signal is an inverted signal of the first: selection signal.

10. The image sensor of claim 1, wherein the light receiving section includes:
a photoelectric conversion element suitable for generating the photocharges based on the incident light;
a floating diffusion node suitable for storing the photocharges generated in the photoelectric conversion element;
a transmission transistor suitable for transferring the photocharges generated in the photoelectric conversion element to the floating diffusion node based on a transmission signal; and
a reset transistor suitable for resetting the floating diffusion node based on a reset signal.

11. An image sensor comprising:
a first node set to a first voltage;
a second node set to a second voltage;
a light receiving section coupled between the first node and the second node;
a first source follower transistor coupled to the first node;
a first selection transistor coupled between the first source follower transistor and a first column line and controlled by a first row line;
a second source follower transistor coupled to the second node;
a second selection transistor coupled between the second source follower transistor and a second column line and controlled by a second row line; and
an output section coupled to the first and second column lines.

12. The image sensor of claim 11, wherein the first and second source follower transistors and the first and second selection transistors include MOS transistors having conductivity types that are complementary.

13. The image sensor of claim 12, wherein the first source follower transistor and the second source follower transistor have conductivity types that are complementary.

14. The image sensor of claim 12, wherein the first source follower transistor and the first selection transistor have the same conductivity type, and the second source follower transistor and the second selection transistor have the same conductivity type.

15. The image sensor of claim 11, wherein the output section merges values of the first column line and the second column line to provide the merged value to one final column line.

16. The image sensor of claim 11, wherein the light receiving section includes:
a photoelectric conversion element coupled to the second node;
a reset transistor coupled to the first node; and
a transmission transistor coupled between the photoelectric conversion element and the reset transistor.

17. The image sensor of claim 16, wherein gates of the first source follower transistor and the second source follower transistor are coupled to a floating diffusion node that is a common node of the transmission transistor and the reset transistor.

18. An image sensor comprising:
a pixel array in which a plurality of unit pixels are arranged in a matrix structure;
a plurality of row lines each including first and second conductive row lines driven by differential selection signals generated in a row driver unit;
a plurality of column lines each including first and second conductive column lines corresponding to first and second output voltages generated in a selected unit pixel;
an output control unit suitable for generating an image signal based on the first and second output voltages, wherein the output control unit includes a plurality of output sections corresponding to the respective column lines; and
a sampling unit coupled to the output control unit to sample the image signal.

19. An image sensor comprising:
a first substrate including a plurality of light receiving sections each suitable for generating photocharges based on incident light;
a first circuit layer formed on the first substrate;
a second circuit layer formed on a second substrate; and
a connector suitable for electrically coupling the first circuit layer to the second circuit layer,
wherein each of a plurality of unit pixels corresponding to the respective light receiving sections includes;
a first driving section suitable for transferring a first output voltage corresponding to a first voltage to a first column line based on the photocharges generated in the light receiving section;
a second driving section suitable for transferring a second output voltage corresponding to a second voltage to a second column line based on the photocharges generated in the light receiving section; and
an output section suitable for outputting an image signal based on the first and second output voltages.

20. The image sensor of claim 19, wherein the first substrate and the second substrate are bonded such that the first circuit layer and the second circuit layer face each other.

21. The image sensor of claim 20, wherein the first driving section and the second driving section include one or more MOS transistors, respectively, and have conductivity types that are complementary.

22. The image sensor of claim 21, wherein the first circuit layer includes the first driving section, and
the second circuit layer includes the second driving section.
